(19) United States
(12) Patent Application Publication
(10) Pub. No.: US 2001/0040262 A1
(43) Pub. Date: Nov. 15, 2001

(54) Semiconductor sensor chip, method of manufacturing the same, and semiconductor sensor having the same

(76) Inventors: Shinji Uchida, Kanagawa (JP); Katsumichi Ueyanagi, Nagano (JP)

Correspondence Address: ROSSI & ASSOCIATES, P.O. BOX 826, ASHBURN, VA, 20146-0826, US

(21) Appl. No.: 09/837,842

(22) Filed: Apr. 18, 2001

(30) Foreign Application Priority Data
Apr. 18, 2000 (JP) 2000-117072

(51) Int. Cl. H01L 21/00; H01L 29/84

(52) U.S. Cl. 257/415; 438/50

(57) ABSTRACT

The present invention provides a semiconductor sensor chip, which comprises a physical quantity sensing part provided on a silicon substrate, and a wiring part for transmitting a physical quantity, sensed by the physical quantity sensing part, as an electric signal, the semiconductor sensor chip comprising: a silicon cap covering the physical quantity sensing part and a part of the wiring part; a junction layer where an end of the silicon cap and the silicon substrate are tightly joined; wherein the silicon cap has an end and a cavity and also has a substantially U-shaped section, and there is provided a predetermined clearance between the junction layer and the physical quantity sensing part.

### BACKGROUND OF THE INVENTION

1. Field of the Invention

The present invention generally relates to a semiconductor sensor chip, in which a physical quantity detecting part is protected by a cap made of silicon (hereinafter referred to as a silicon cap), a method of manufacturing the semiconductor sensor chip, and a semiconductor sensor provided with the semiconductor sensor chip.

2. Description of Related Art

Semiconductor sensors are used in various fields such as the medical industry, the car industry, the measurement and calibration in the precision machinery industry and so forth. Examples of semiconductor sensors are an acceleration sensor, a pressure sensor and an angular acceleration sensor. The following description relates to the acceleration sensor.

A sensor chip for use in the semiconductor acceleration sensor is constructed, e.g., by providing a silicon substrate with an acceleration sensing part comprised of a weight and a beam, and a wiring part for outputting a displacement of the acceleration sensing part as a change in the quantity of static electricity. The semiconductor acceleration sensor, which is provided with the sensor chip constructed in the above-mentioned manner, detects the acceleration in a manner described hereinbelow. When the acceleration is applied to the semiconductor acceleration sensor, the weight and the beam for supporting it at the acceleration sensing part move according to the low of inertia to thereby change the quantity of static electricity at the acceleration sensing part. The change in the quantity of static electricity is transduced into an electric signal by a circuit provided outside the sensor chip. According to the output of the electric signal, it is determined that the acceleration is occurring (i.e., the acceleration is detected).

In order that the above semiconductor acceleration sensor may achieve a more excellent sensing characteristic, the acceleration sensing part composed of the weight and the beam supporting it is preferably protected from factors (moisture or foreign matters) that may cause detection errors. Accordingly, several measures have been taken for the purpose of protecting the acceleration sensing part from the moisture and the foreign matters in a dicing step of separating the silicon wafer into separate chips after the formation of the acceleration sensing part on the silicon wafer, and for the purpose of protecting the acceleration sensing part from mold resin in a molding step of molding the chips. To improve the detection sensitivity and stabilize the sensing characteristic, the periphery of the acceleration sensing part preferably is desired to be in inert gas atmosphere or vacuum atmosphere, and the cap is desired to have such an excellent sealing performance that the end thereof is tightly joined to the substrate.

An anode junction method, an eutectic junction method and a direct junction method are known as examples of methods for joining the cap to the acceleration sensing part of the acceleration sensor chip. In the anode junction method, a high voltage is applied between a silicon wafer provided with an acceleration sensing part and a cap made of glass. In the eutectic junction method, a silicon wafer provided with an acceleration sensing part and a silicon cap, which is produced by plating or evaporating Au, are heated up to a temperature of not lower than a eutectic point of Au-Si. In the direct junction method, the surface of a silicon cap is controlled at the particle level to covalently bond a silicon wafer provided with an acceleration sensing part to the silicon cap on the silicon surface.

These conventional junction methods have the disadvantages as described below.

The anode junction method has the following four problems. First, there is the necessity of using a glass cap in order to join the cap itself directly to the silicon substrate. Due to a difference in the thermal expansion coefficient between glass and silicon, a stress residues when the cap and the silicon substrate are joined by heating at a temperature of 200° C. - 400° C. This causes errors in the sensing operation of the acceleration sensing part, which is sensitive to the stress. For example, the sensing characteristic varies according to the change in temperature. Second, there is the necessity of applying a high voltage of several-hundred volt during the joining process. Thus, static electricity absorbing force is generated between the acceleration sensing part and the cap when the voltage is applied. This static electricity absorbing force causes damage to the acceleration sensing part or causes sensing errors. Third, if leading wires extending from the acceleration sensing part are formed of metal, a junction surface is uneven at a part where the metal leading wires are crossed. This deteriorates the sealing performance of the cap. Fourth, there is the necessity of cutting silicon and glass, which are different kinds of materials, when the silicon wafers are diced into separate chips. This accelerates the wear of a dicing blade.

In the case of the eutectic junction method, a natural oxide film is easily formed because the silicon is extremely active. This makes it difficult to form a eutectic area over the whole surface of the silicon wafer with a large diameter. Moreover, a void is easily formed at the junction. The formation of the void at the junction results in the irregularity in junction intensity. Further, it is impossible to join the silicon wafer and the silicon cap across the metal leading wires formed on the surface of the silicon substrate because Au has a high conductivity. To address this problem, for example, the leading wires should be made of semiconductor.

In the case of the direct junction method, the cap is bonded at the particle level, and therefore, the surface is required to be flat at the particle level. This requires a very high cost. Moreover, the direct junction method may only be applied to special material because the junction surface is difficult to control.

### SUMMARY OF THE INVENTION

It is therefore an object of the present invention to provide a semiconductor sensor chip in which a physical quantity sensing part is joined to a cap, the semiconductor sensor chip which does not have any problems pertaining to the above-mentioned anode junction method, the eutectic junction method and the direct junction method, does not badly influence the sensing characteristic, and achieves an excellent sealing performance even if the metal leading wires are formed on the surface of the silicon substrate.

It is another object of the present invention to provide a manufacturing method that provides the low-cost and preferable joining conditions to simplify the step of joining the cap to the physical quantity sensing part, thereby enabling the mass production of semiconductor sensor chip with high accuracy and reliability.

The above object can be accomplished by providing a semiconductor sensor chip, which comprises a physical quantity sensing part provided on a silicon substrate and a wiring part for transmitting a physical quantity, sensed by the physical quantity sensing part, as an electric signal, the semiconductor sensor chip comprising: a silicon cap covering the physical quantity sensing part and a part of the wiring part; a junction layer where an end of the silicon cap and the silicon substrate are tightly joined; and wherein there is provided a predetermined clearance between the junction layer and the physical quantity sensing part.

In one preferred form, the junction layer is formed of a composition including low-fusing point glass.

In one preferred form, a thermal expansion coefficient of the composition including the low-fusing point glass is not greater than 60×10⁻⁷/C. °.

In one preferred form, the composition including the low-fusing point glass includes a filler selected from a group comprising Pb—Ti—O, A1₂O₂ and Si—Al—O.

In one preferred form, the low-fusing point glass is selected from a group comprising PbO—B₂O₃, PbO—SiO₂ and PbO—B₂B₃—SiO_{2.}

In one preferred form, the predetermined clearance is not less than 50μm.

In one preferred form, the junction layer has a width of not greater than 300μm and a thickness of not greater than 50μm.

In one preferred form, a maximum particle size of the filler is not greater than 50μm.

In one preferred form, the junction layer includes high polymer resin.

In one preferred form, the high polymer resin is polyimide.

A semiconductor sensor according to the present invention comprises the semiconductor sensor chip in any one of above preferred forms.

The above object can also be accomplished by providing a first method of manufacturing a semiconductor sensor chip, which comprises joining a silicon cap composed of a first silicon wafer and a silicon substrate composed of a second silicon wafer having a physical quantity sensing part and a wiring part through a junction layer composed of a low-fusing point glass composition, the method comprising: a first step of forming a low-fusing point glass film on a whole surface of one side of the first silicon wafer; a second step of forming a junction layer, cavities and through parts in the first silicon wafer having the low-fusing point glass film formed in the first step; a third step of joining the first silicon wafer processed in the first and second steps and the second silicon wafer having the physical quantity sensing part and the wiring part to thus form a joined body; and a fourth step of dicing the joined body formed in the third step into semiconductor sensor chips.

The above object can also be accomplished by providing a second method of manufacturing a semiconductor sensor chip, which comprises joining a silicon cap composed of a first silicon wafer and a silicon substrate composed of a second silicon wafer having a physical quantity sensing part and a wiring part through a junction layer including high polymer resin, the method comprising: a first step of forming the junction layer by applying a film, including high polymer resin and stamped in a predetermined shape, to one side of the first silicon wafer; a second step of forming cavities and through parts in the first silicon wafer having the junction layer formed in the first step; a third step of joining the first silicon wafer processed in the first and second steps and the second silicon wafer having the physical quantity sensing part and the wiring part to thus form a joined body; and a fourth step of dicing the joined body formed in the third step into semiconductor sensor chips.

In this method, the high polymer resin is preferably polyimide.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1(a) is a perspective showing a semiconductor acceleration sensor chip as one example of a semiconductor chip according to the present invention, and FIG. 1(b) is a sectional view taken along line A-A′ in FIG. 1(b);

FIG. 2 is a perspective view showing the semiconductor acceleration sensor chip with its cap being detached as one example of the semiconductor sensor chip according to the present invention;

FIG. 3 is a conceptual wiring diagram of an acceleration sensing part in the semiconductor acceleration sensor chip as one example of the semiconductor sensor chip according to the present invention;

FIG. 4 is a graph showing a relationship between a thermal expansion coefficient and Voff characteristics of a low fusing point composition that may be applied to the semiconductor sensor chip according to the present invention;

FIG. 5 is a graph showing a relationship between the maximum particle diameter of a filler and the thickness of a junction layer;

FIG. 6 is a block diagram showing an embodiment of a semiconductor acceleration sensor as one example of a semiconductor sensor according to the present invention;

FIG. 7 is a conceptual sectional view showing the first method of manufacturing the semiconductor acceleration sensor chip as one example of the semiconductor sensor chip according to the present invention;

FIG. 8 is a flow chart of assistance in explaining the first method of manufacturing the semiconductor acceleration sensor chip as one example of the semiconductor sensor chip according to the present invention;

FIGS. 9(a)-9(c) are conceptual sectional views showing the steps in the second method of manufacturing the semiconductor acceleration sensor chip as one example of the semiconductor sensor chip according to the present invention; and

FIG. 10 is a flow chart of assistance in explaining the second method of manufacturing the semiconductor acceleration sensor chip as one example of the semiconductor sensor chip according to the present invention.

### DETAILED DESCRIPTION OF THE PREFERRED EMBODIMENTS

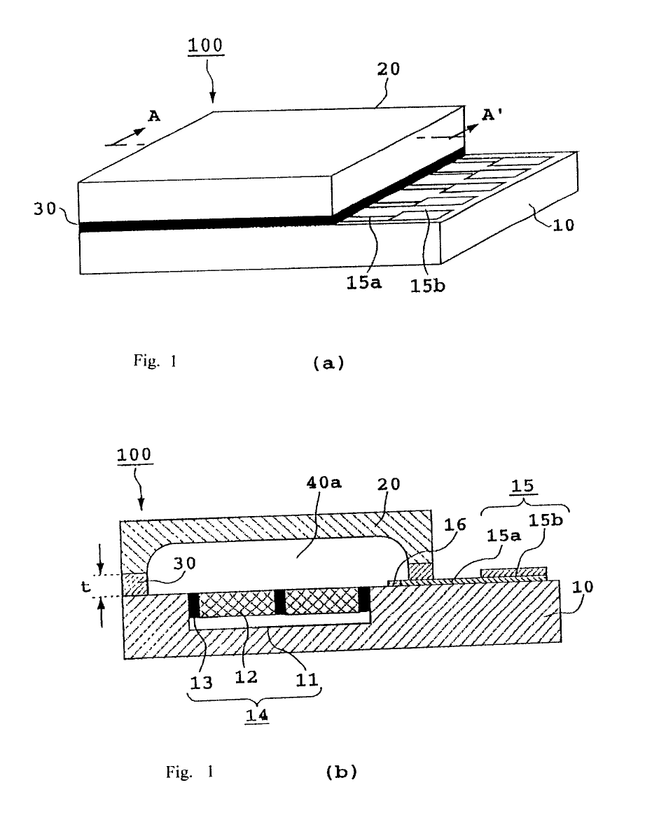

Referring to FIGS. 1 and 2, there will hereunder be described the structure of a semiconductor acceleration sensor chip as an example of a semiconductor sensor chip according to the present invention.

FIG. 1(a) is a perspective view a semiconductor acceleration sensor chip as an example of a semiconductor sensor chip according to the present invention, and FIG. 1(b) is a sectional view taken along line A-A′ in FIG. 1(a).

As shown in FIG. 1(a), a semiconductor acceleration sensor chip 100 is comprised of a silicon substrate 10, a silicon cap 20 arranged on the silicon substrate, and a junction layer 30 where the silicon substrate 10 and the silicon cap are joined.

As shown in FIG. 1(b), the silicon substrate 10 has an acceleration sensing part 14 as a physical quantity sensing part, and a wiring part 15 for transmitting the physical quantity (acceleration), which is sensed by the acceleration sensing part 14, as an electric signal. The acceleration sensing part 14 comprises: a support frame 11 that is composed of the periphery of a cavity formed by cutting the surface of the silicon substrate 10; a weight 12 that is disposed inside the support frame 11 and is capable of moving according to the acceleration; and a beam that connects with the support frame 11 to support the weight 12. The wiring part 15 comprises leading wires 15a for transmitting the change in stress, which is generated by the movement of the weight 12 provided in the acceleration sensing part 14, as an electric signal; and electrode pads 15bs. As the need arises, the wiring part 15 is also provided with adjusting resistances 16. The wiring part 15 is made of aluminum, copper or equivalent material. A diffusion layer formed on the silicon substrate 10 may be used as the leading wires 15a. A protection film (not shown) composed of a silicon oxide film or a silicon nitride film, or a protection film (not shown) composed of the silicon oxide film and the silicon nitride film is provided on the wiring part 15 and the adjusting resistances 16. Since such a protection film is known to those skilled in the art, a detailed description thereof will be omitted.

The silicon cap 20 is a lid-shaped member that comprises an end, which is not in contact with the acceleration sensing part 14 and has a substantially U-shaped section; and a cavity 40a. The end of the silicon cap 20 is tightly joined to the silicon substrate 10 through the junction layer 30. This forms a sealed space, which is comprised of the cavity 40a in the silicon cap 20 and the support frame 11, around the acceleration sensing part 14.

In the process of manufacturing the silicon cap, a junction layer formed of a joining agent is provided on the entire surface of the end of the silicon cap, and the silicon cap and the junction layer are integrated together so that the silicon substrate and the silicon cap can be joined easily.

FIG. 2 is a perspective view showing the state wherein the silicon cap 20 is detached from the semiconductor acceleration sensor chip of the present invention in FIG. 1. Diagonal lines in FIG. 2 indicate the junction between the silicon cap 20 and the silicon substrate 10. One end of each leading wire 15a extends to the outside of the cap across a part where the silicon cap 20 is joined to the silicon substrate 10. The electrode pads 15b are provided on the leading wires 15a extending to the outside of the silicon cap 20.

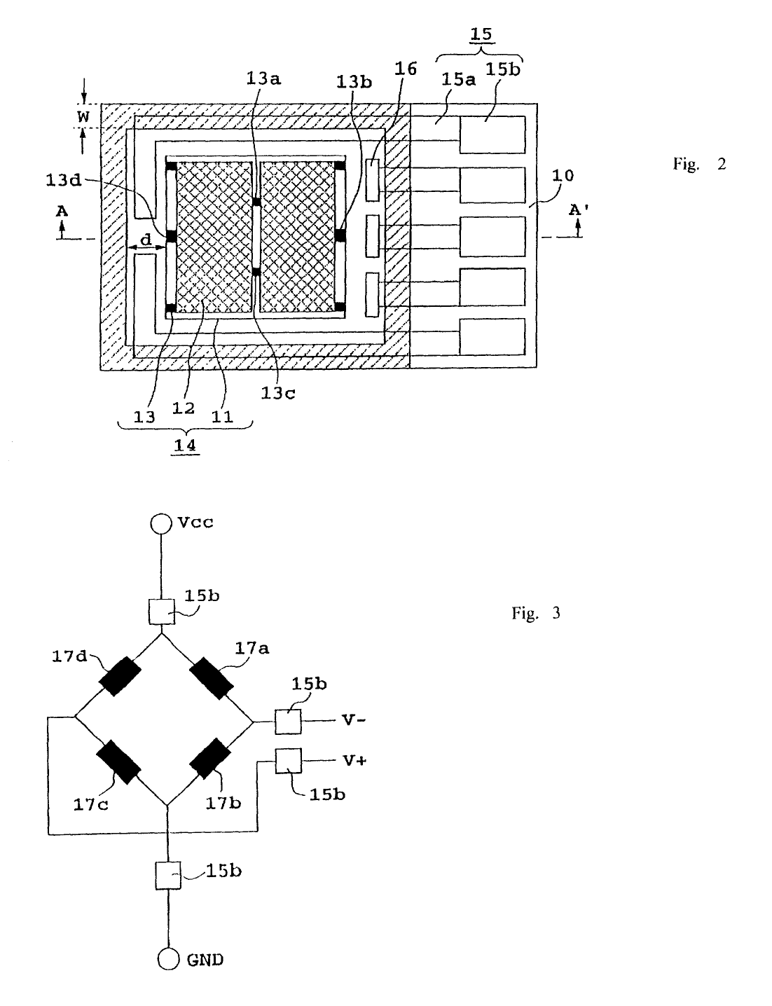

FIG. 3 shows an equivalent circuit of the acceleration sensing part 14 provided on the silicon substrate. Semiconductor strain gauges 17a, 17b, 17c and 17d are formed in the beams 13a, 13b, 13c and 13d, respectively, by the diffusion of impurities. These four semiconductor strain gauges form a Wheatstone bridge as shown in FIG. 3. The Wheatstone bridge is connected to the electrode pads 15b through the leading wire 15a which are connected to a constant-voltage supply part VCC, a gland GND, and output parts V₊, V₋by bonding aluminum wires.

In the semiconductor acceleration sensor chip of the present invention, the silicon substrate and the silicon cap are integrated through the junction layer. The joining agent, which forms the junction layer, is preferably a low-fusing point glass composition or high polymer resin that can be deformed by heating. The use of the low-fusing point glass composition or the high polymer resin as the joining agent makes it possible to keep the sealed state between the silicon substrate and the silicon cap even if the junction layer crosses the leading wires formed on the surface of the silicon substrate.

The use of the low-fusing point glass composition or the high polymer resin as the joining agent eliminates the necessity of using a glass cap as in the case of a conventional anode junction method. It is therefore possible to use the silicon cap, which is made of the same material as that of the silicon substrate. This substantially eliminates a difference in thermal expansion between the cap and the substrate, and prevents the deterioration in the sensing characteristic of the semiconductor acceleration sensor, which results from the difference in the thermal expansion. Since the cap and the substrate are made of substantially the same material, it is possible to easily dice a joined body, which is produced by joining the cap and the substrate, at a low cost. Moreover, there is no possibility of the deterioration in the sensing characteristic, which is caused by the application of the voltage as in e.g., the anode junction method.

In order to further improve the performance of the semiconductor acceleration sensor chip according to the present invention, it is necessary to further study the conditions of the junction layer such as a thermal expansion coefficient of the joining agent forming the junction layer, a thickness “t” of the junction layer (refer to FIG. 1(b)), a width “w” of the junction layer and a distance “d” between the junction layer and the acceleration sensing part (see FIG. 2). A description will now be given of the case where the low-fusing point glass composition is used as the joining agent.

1. The study of the thermal expansion coefficient of the low-fusing point glass composition.

To reduce the errors in the sensing characteristic, it is important to set the thermal expansion coefficient of the low-fusing point glass, which is used for joining the silicon cap and the substrate, to a value approximate to the thermal expansion coefficient of the silicon substrate. Accordingly, it is preferable to set the thermal expansion coefficient of the low-fusing point glass for use in the junction to a value within the range between 20×10⁻⁷/° C. and 60×10⁻⁷/° C., with the thermal expansion coefficient of the silicon substrate being taken into consideration.

As examples of the low-fusing point glass, PbO—B₂O₃, PbO—SiO₂ and PbO—B₂O₃—SiO₂ are known to those skilled in the art. According to the present invention, PbO—B₂O₃—SiO₂ is used as the low-fusing point glass to produce the low-fusing point glass composition. A filler such as Pb—Ti—O, Al₂O₃ and Si—Al—O is added to the low suing point glass in order to adjust the thermal expansion coefficient of the low-fusing point glass composition. Although there is no limitation on the kinds of the fillers to be added, it is preferable to add Pb—Ti—O that is relatively stable in the low-fusing point glass.

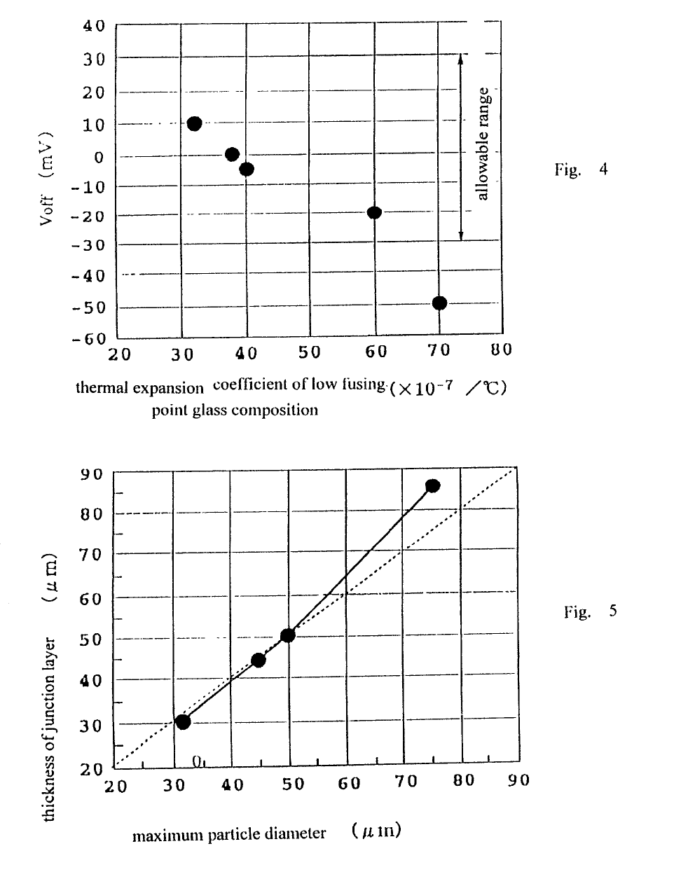

For the reasons stated above, the low-fusing point glass compositions were produced by using PbO—B₂O₃—SiO₂ as the low-fusing point glass and Pb—Ti—O as the filler. Five kinds of low-fusing point glass compositions were produced by changing the quantity of the filler added to the low-fusing point glass. The thermal expansion coefficients of these five resulting five low-fusing point glass compositions were 32×10⁻⁷/° C., 38×10⁻⁷/° C., 40×10⁻⁷/° C., 60×10⁻⁷/° C., and 70×10⁻⁷/° C., respectively. Test samples were obtained by joining the silicon caps, which have the junction layers formed by those low-fusing point glass compositions, to the silicon substrates, each of which is provided with the acceleration sensing part and the wiring part. The Voff characteristic in each test sample was studied. FIG. 4 shows the Voff characteristic in each test sample.

A Voff value is calculated by the following equation: (Voff)=(V_)−(V₊) when the constant voltage supply part Vcc is connected to the Wheatstone bridge of the semiconductor acceleration sensor chip in FIG. 3. The Voff value is one of factors to be used in the evaluation of the sensing characteristic. The Voff value varies according to the stress applied to the acceleration sensing part. An ordinary allowable range of the Voff value is between −30mV and +30mV. If the Voff value lies outside this allowable range, the acceleration sensing part excessively distorts due to the stress that is applied to the acceleration sensor from the outside. This is undesirable in respect of the sensing stability and reliability.

As is apparent from FIG. 4, if the thermal expansion coefficient of the low fusing point is 70×10⁻⁷/° C., the Voff value varies to a large degree and finally goes beyond the above-mentioned allowable range. Usually, it can be considered that the variation in the Voff value is reduced by increasing the distance “d” between the junction and the acceleration sensing part (see FIG. 2). This, however, cannot achieve a desirable effect because the increase in the distance “d” between the junction and the acceleration sensing part would increase the size of the sensor chip. On the other hand, it was turned out that a satisfactory sensing characteristic, in which there is only a small variation in the Voff value, could be achieved by adjusting the thermal expansion coefficient of the low-fusing point glass, which joins the silicon cap and the substrate, to a value of not greater than 60×10⁻⁷/° C. without increasing the distance “d” between the junction and the acceleration sensing part. It is therefore preferable to select suitable low fusing glass and filler and adjust the thermal expansion coefficient of the low-fusing point glass composition to a value within the range between 20×10⁻⁷/° C. and 60×10⁻⁷/° C.

CaO, MgO, ZnO and the like may be added to PbO—B₂O₃—SiO₂ that is used as the low-fusing point glass. As the need arises, it is possible to further add a known additive such as an antioxidant and an ultraviolet stabilizer to the low-fusing point glass composition.

2. The study of the dimensions of the junction layer

The Voff value also varies according to the following dimensions of the junction layer: the distance “d” between the junction layer and the acceleration sensing part, the thickness “t” of the junction layer, and the width “w” of the junction layer.

Particularly if the low-fusing point glass is used as the joining agent, the Voff value is greatly influenced by the dimensions of the junction layer. For this reason, PbO—B₂O₃—SiO with the thermal expansion of 30×10⁻⁷/° C. was used as the joining agent, and a variety of semiconductor acceleration sensors having junction layers with different dimensions were manufactured in order to study a relationship between the Voff values and the dimensions of the junction layers. Table 1 shows the result of the study.

Table 1

The relationship between the dimensions of the junctions and the Voff values.

| | Distance d between | | | |
|---|---|---|---|---|
| | the junction layer | Width w of | Thickness t of | Judgment |
| | and the acceleration | the junction | the junction | about |
| Sample | sensing part (μm) | layer (μm) | layer (μm) | Voff* |
| 1 | 30 | 250 | 30 | x |
| 2 | 30 | 400 | 30 | x |
| 3 | 30 | 400 | 50 | x |
| 4 | 30 | 400 | 80 | x |
| 5 | 50 | 250 | 30 | □ |
| 6 | 50 | 300 | 30 | □ |
| 7 | 50 | 400 | 30 | x |
| 8 | 50 | 250 | 50 | □ |
| 9 | 50 | 300 | 50 | □ |
| 10 | 50 | 400 | 50 | x |
| 11 | 50 | 250 | 80 | x |
| 12 | 50 | 300 | 80 | x |

*note:
A mark □ indicates that the Voff value lies inside the allowable range (i.e., between −30 and +30), and a mark x indicates that the Voff value lies outside the allowable range.

As is apparent from the Table 1, a satisfactory sensing characteristic can be achieved in the case where the distance “d” between the acceleration sensing part and the junction layer is not less than 50μm, the width “w” of the junction layer is not greater than 300μm and the thickness “t” of the junction layer is not greater than 50μm. More particularly, the width “w” of the junction layer is preferably between 10μm and 300μm because the reduction in the width “w” lowers the intensity of the junction. The thickness “t” of the junction layer is preferably between 20μm and 50μm because the reduction in the thickness “t” lowers the intensity of the junction.

3. The study of a relationship between the particle size of the filler

and the thickness of the junction layer

By observing the section of the sensor chip manufactured in the above-described study through a microscope, it was found out that the thickness “t” of the junction layer was 30μm equal to the maximum particle size of PbO—B₂O₃—SiO₂ that was used as the filler. This turned out that the filler never changed its shape even at a junction temperature of PbO—B₂O₃—SiO₂ used as the low-fusing point glass, and that the thickness “t” of the junction layer could be controlled accurately by changing the particle size of the filler. For this reason, a relationship between the particle size of the filler and the thickness “t” of the junction layer was further studied.

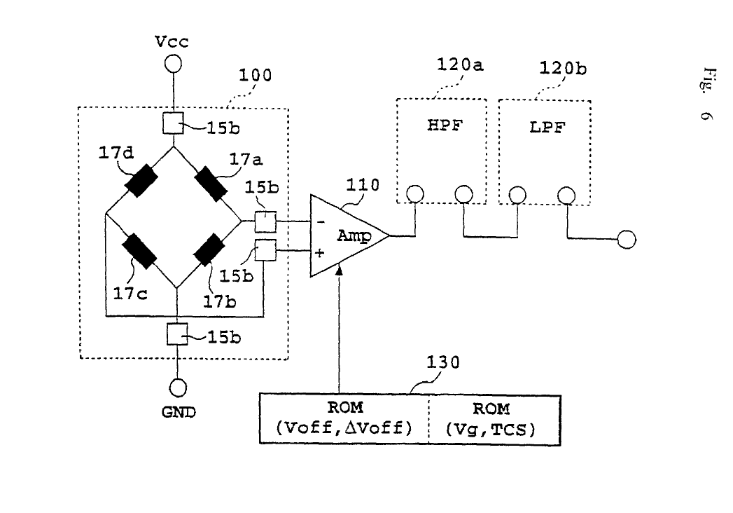

In this study, low-fusing point glass components were produced by using PbO—B₂O₃—SiO₂ as the low-fusing point glass and adding a predetermined amount of Pb—Ti—O with different particle sizes to the low-fusing point glass. Fillers with the maximum particle sizes of 32μm, 45μm, 50μm and 75μm were used. Test samples were taken by manufacturing silicon caps by using such low-fusing point glass compositions, and joining the silicon caps and silicon substrates. The thickness “t” of each junction layer was studied. FIG. 5 shows the results of the study.

As shown in FIG. 5, the thickness “t” of the junction layer is 30μm if the maximum particle size is 32μm, the thickness “t” is 44μm if the maximum particle size is 44μm, the thickness “t” is 50μm if the maximum particle size is 32μm, and the thickness “t” was 75μm if the maximum particle size is 85μm. If the maximum particle size of the filler is not greater than 50μm, the maximum particle size and the thickness “t” of the junction layer are substantially equal. Therefore, the maximum particle size of the filler is set to a value of not greater than 50μm in order that the thickness “t” of the junction layer may be a value of not greater than 50μm.

In order that the filler may function satisfactorily in dimensioning the junction layer, the quantity of the filler is preferably within the range between 10wt% and 85wt%, and more preferably between 40wt% and 75wt% with respect to the low-fusing point glass composition. Those skilled in the art, however, would easily understand that there is the necessity of adjusting the quantity of the added filler in relation to the thermal expansion coefficient because the filler is also used for the purpose of adjusting the thermal expansion coefficient of the low-fusing point glass composition.

For the reasons stated above, the thermal expansion coefficient of the low-fusing point glass, which joins the silicon cap and the silicon substrate, is preferably between 20×10⁻⁷/° C. and 60×10⁻⁷/° C. approximate to the thermal expansion coefficient of the silicon substrate, which has the acceleration sensing part and the wiring part.

Moreover, the junction layer, which encloses the acceleration sensing part and a part of the wiring part on the silicon substrate and where the silicon cap and the silicon substrate are joined, are preferably dimensioned as follows. The distance “d” between the junction layer and the acceleration sensing part is preferably not less than 50μm; the width “w” of the junction layer is preferably not greater than 300μm; and the thickness “t” of the junction layer is preferably not greater than 50μm.

By setting the thermal expansion coefficient of the joining agent forming the junction layer and dimensioning the junction layer in the above-mentioned manner, the stress residing in the cap after the junction can be reduced to an extremely small amount to thereby prevent the bad influence on the sensing characteristic. It is therefore possible to provide the semiconductor acceleration sensor chip that is able to achieve an excellent temperature characteristic while it is in use.

If the low-fusing point glass composition is used as the joining agent, the low glass fusing point is preferably comprised of the low-fusing point glass, which is selected from a group comprising PbO—B₂O₃, PbO—SiO₂ and PbO—B₂O₃—SiO₂, and the filler composed of Pb—Ti—O. The use of the above-stated low-fusing point glass can lower a temperature at which the silicon cap is joined to the substrate, and the addition of the filler can restrain the thermal expansion coefficient. Moreover, the thickness of the junction layer can be accurately adjusted to a value of not greater than 50μm by setting the maximum particle size of the filler to a value of not greater than 50μm.

The above studies relate to the low-fusing point glass composition, but the high polymer resin may be used as the joining agent. Preferably, the high polymer resin for use the joining agent is strongly adhered to the silicon substrate, generates only a small amount of gas, has a low hydrophilia and hygroscopicity and a high air sealing performance, and is easy to handle when it is used as a sheet. Examples of the high polymer resin are polyimide and epoxy resin. Although there is no particular limitation on the kinds of the high polymer resins, it is preferable to use the polyimide that is strongly adhered to the silicon substrate, generates a small amount of gas, has a low hygroscopicity and is easy to handle when it is used as a film. An additive, which is known to those skilled in the art, such as an antioxidant and a ultraviolet stabilizer may be added to the high polymer resin used as the joining agent as the need arises.

FIG. 6 is a block diagram showing an example of a semiconductor acceleration sensor provided with the semiconductor acceleration sensor chip, which is one example of the semiconductor sensor chip according to the present invention. As shown in FIG. 6, the semiconductor acceleration sensor comprises a semiconductor acceleration sensor chip 100, an amplifier circuit 110, a high-pass filter 120, a low-pass filter 120b and a digital control circuit 130.

An output from the semiconductor acceleration sensor chip 100 is amplified by an amplifier circuit 110, and goes through the high-pass filter 120a and the low-pass filter 120b to result in an output Vout. Data VG for use in correcting the sensitivity, data TCS for use in correcting a temperature characteristic of the sensitivity, an offset voltage Voff (a sensor output in the state where no acceleration is applied), and a correction value Δ for use in correcting the deviations of the offset voltage is transmitted from the digital control circuit 130 to the amplifier circuit 110.

The high-pass filter 120a and the low-pass filter 120b may be external circuits. Alternatively, a control part for such frequency response bandwidths, and the like may be incorporated into the digital control circuit 130. Besides, those skilled in the art would easily understand that the semiconductor acceleration sensor chip of the present invention might be incorporated into various forms of sensors. Moreover, the acceleration sensor chip 100 and the electronic circuits such as the amplifier circuit 110 may constitute one chip.

There will now be described a method of manufacturing the semiconductor acceleration sensor chip.

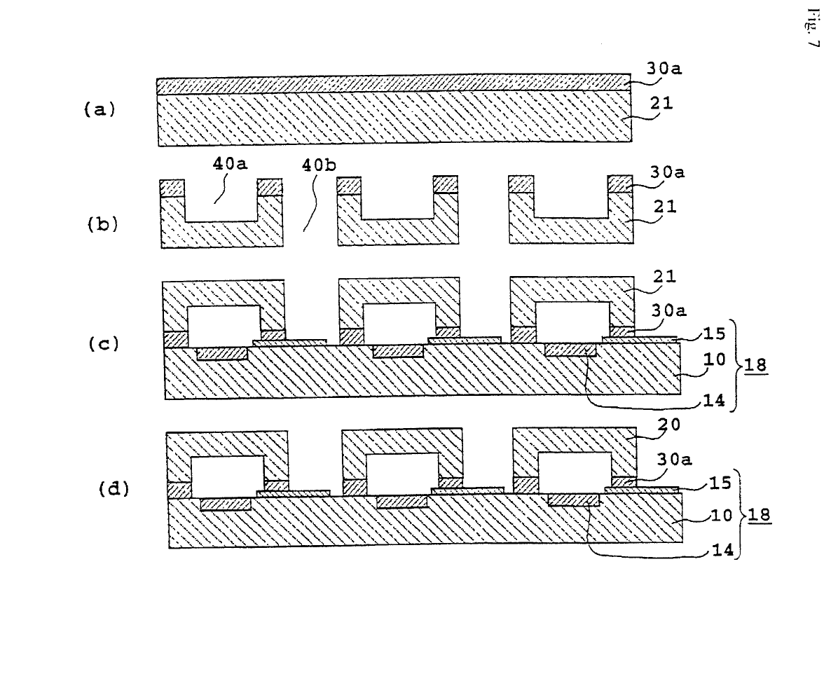

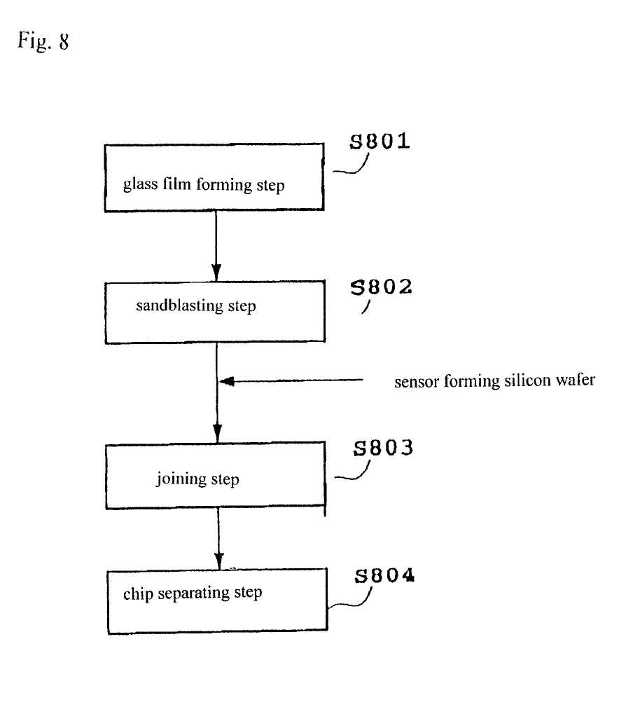

Referring now to FIGS. 7 and 8, a description will be given of the method of manufacturing the semiconductor acceleration sensor chip as one example of the semiconductor sensor chip according to the present invention wherein the low-fusing point glass composition is used for joining the silicon cap and the silicon substrate. FIGS. 7(a) through 7(d) are conceptual sectional views showing the steps in the method of manufacturing the semiconductor acceleration sensor chip. FIG. 8 is a flow chart describing the method of manufacturing the semiconductor acceleration sensor chip.

First, a low-fusing point glass film is formed as a junction layer 30aon the entire surface of one side of a first silicon wafer 21 as shown in FIG. 7(a) in e.g., the following manner (S801). A paste of the low-fusing point glass composition is coated and is then heated, so that binders are removed from the low-fusing point glass composition and the low-fusing point glass is temporarily sintered.

Next, as shown in FIG. 7(b), a protection film (not shown) is formed at a predetermined position on the low-fusing point glass film, and the junction layer 30a and the first silicon wafer 21 are sandblasted to thereby form a plurality of cavities 40a and a plurality of through parts 40b between the adjacent cavities 40a (S802). In FIG. 7(b), it seems as if the formation of the through parts 40b divided the first silicon wafer 21 into separate chips. Actually, however, the first silicon wafer 21 are not divided into separate chips because the chips are connected to one another in an area not shown.

In the process of sandblasting, the low-fusing point glass film and the first silicon wafer 21 can be cut at the same time beginning from the part of the low-fusing point glass film as the junction layer 30a. It is therefore unnecessary to form the low suing point glass film by patterning or etch the low-fusing point glass film at two stages. The sandblast process, however, should not necessarily be executed. It is possible to etch the low-fusing point glass film and anisotropically etch the silicon wafer.

Next, as shown in FIG. 7(c), a second silicon wafer 18 (also referred to as a sensor forming silicon wafer) provided with the acceleration sensing part 14, the wiring part 15 and a protection film formed on the wiring part 15, and the first silicon wafer 21 processed in the previous step are joined in a manner described below. (S803). First, the silicon wafers 18, 21 are positioned with respect to each other, and a spring clamp temporarily fastens these silicon wafers at their peripheries. The temporarily fastened first silicon wafer 21 and sensor forming silicon wafer 18 are then inserted into a hot-press furnace. The internal atmosphere is replaced by nitride at a temperature in close proximity to a room temperature, is then heated to 400-500° C. and is pressurized by a pressure of 5−20×10⁴Pa. The sensor forming silicon wafer 18 can be manufactured by providing a silicon wafer with the acceleration sensing part and the wiring part in a method known to those skilled in the art.

Finally, as shown in FIG. 7(b), a joined body acquired in the previous step is divided into separate semiconductor acceleration sensor chips by dicing (S804).

The manufacture of the semiconductor acceleration sensor chips in the above-mentioned manner eliminates the necessity of masking and positioning the sensor chips when the paste of the low-fusing point glass composition is coated. This simplifies the method of manufacturing the sensor chips. Moreover, it is possible to manufacture the silicon cap composed of the first silicon wafer, on which the low-fusing point glass film as the junction layer is accurately formed.

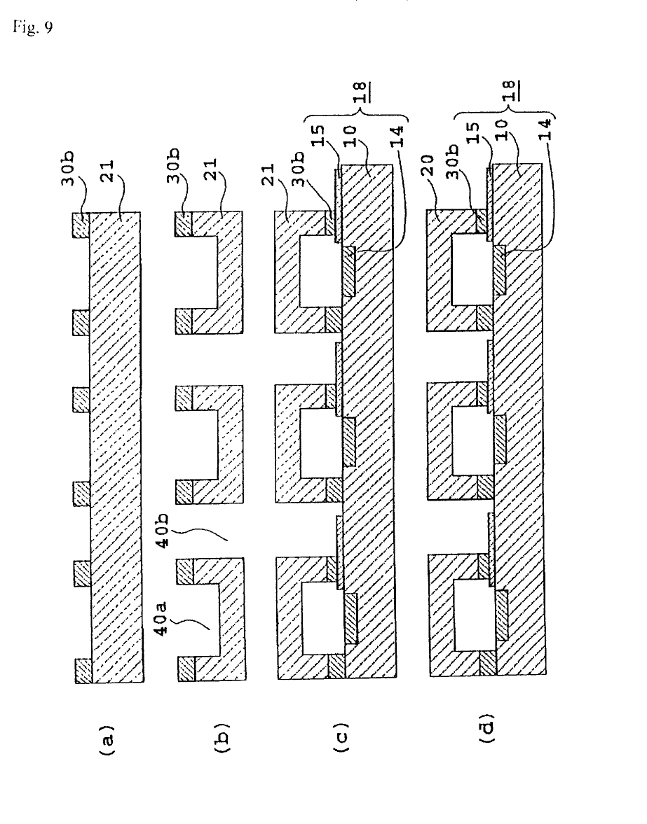

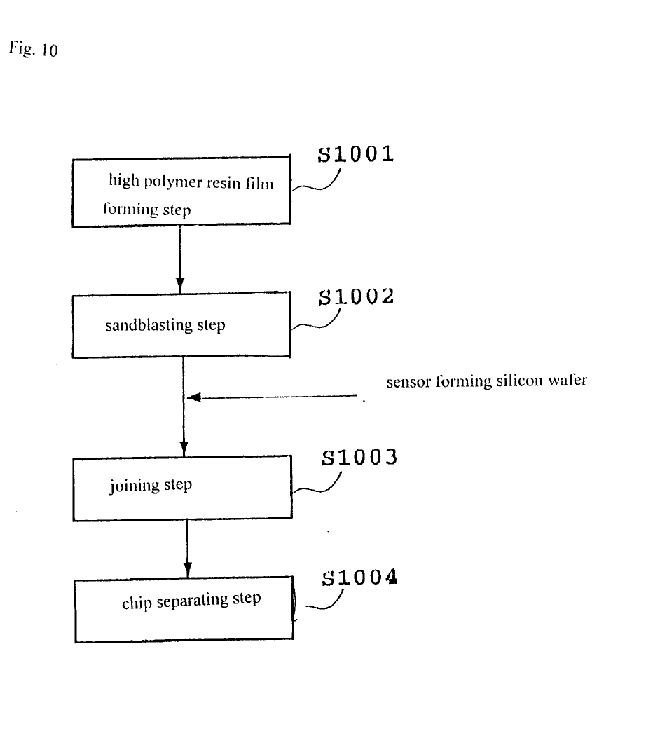

Referring next to FIGS. 9 and 10, there will be described a method of manufacturing the semiconductor acceleration sensor chip as one example of the semiconductor sensor chip according to the present invention wherein the high polymer resin is used for joining the silicon cap and the silicon substrate. FIGS. 9(a) through 9(c) are conceptual sectional views showing the steps in the method of manufacturing the semiconductor acceleration sensor chip. FIG. 10 is a flow chart showing the method of manufacturing the semiconductor acceleration sensor chip.

First, as shown in FIG. 9(a), a high polymer resin film, which is stamped by patterning, is applied to one side of the first silicon wafer 21 by thermal treatment with a load being applied (S1001).

As shown in FIG. 9(b), a protection film (not shown) is formed at a predetermined position on the first silicon wafer 21 having the junction layer 30b, and the first silicon wafer 21 is then sandblasted to form a plurality of cavities 40a and a plurality of through parts 40b between the adjacent cavities 40b (S1002). In FIG. 9(b), it seems as if the formation of the through parts 40b divided the first silicon wafer 21 into separate chips. Actually, however, the first silicon wafer 21 is not divided into separate chips because the chips are connected to one another in an area not shown.

Then, as shown in FIG. 9(c), the second silicon wafer 18 (hereinafter referred to as the sensor forming silicon wafer, too), on which the acceleration sensing part 14, the wiring part 15 and the protection film (not shown) formed on the wiring part 15 are provided, is joined to the first silicon wafer 21 processed in the previous step in the following manner (S1003). The silicon wafers 18, 21 are positioned, and the spring clamp temporarily fastens them together at their peripheries. The temporarily-fastened first silicon wafer 18, 21 are inserted into the hot-press furnace. The internal atmosphere is replaced by nitrogen at a temperature in proximity to a room temperature, and is heated to 400-500° C. and pressurized by pressure of 5−20×10⁴Pa at the same time. The sensor forming silicon wafer 18 can be manufactured by providing the silicon wafer with the acceleration sensing part and the wiring part in a manner known to those skilled in the art.

Further, as shown in FIG. 9(d), the joined body produced in the previous step is diced into separate sensor chips (S1004).

As stated above, the high polymer resin film, which is stamped in advance, is formed as the junction layer of the silicon wafer. It is therefore possible to easily and accurately process the cap having the junction layer even if high polymer resin, which cannot be cut through by sandblasting, is used.

As stated above, each method of manufacturing the semiconductor acceleration sensor chip according to the present invention enables the accurate formation of the junction layer because the silicon wafer (the first silicon wafer 21) provided with the junction layer is used as the material for the cap. Moreover, each method makes it easier to position and join the first silicon wafer and the sensor forming silicon wafer. Further, each method reduces the wear of a dicing blade in the dicing step since the cap and the substrate are made of the silicon wafer. Additionally, the use of the silicon wafers with large diameters makes it easy to mass-produce the sensor chips.

A description will hereunder be given of specific embodiments of the semiconductor sensor chip and the method of manufacturing the same. It should be understood, however, that there is no intention to limit the invention to the embodiments disclosed, but on the contrary, the invention is to cover all modifications, alternate constructions and equivalents falling within the spirit and scope of the invention as expressed in the appended claims.

First Embodiment

The first embodiment relates to the manufacture of a semiconductor acceleration sensor chip in which the low-fusing point glass composition is used to join the cap and the substrate.

A silicon wafer with a diameter of six inches was produced, and a paste of the low-fusing point glass composition was coated on the whole surface of one side of the silicon wafer by a screen painting method. The low-fusing point glass composition was dried at a temperature of 150° C. and was heated to a temperature of 350° C., so that binders were removed from the low-fusing point glass composition and the low-fusing point glass was temporarily sintered. This formed a low-fusing point glass film with a thickness 35μm was formed on the whole surface of one side of the silicon wafer. The low-fusing point glass composition used in the present embodiment was comprised of low-fusing point glass PbO—B₂O₃—SiO₂ and a filler whose the maximum particle size was Pb—Ti—O. The quantity of the filler was 65wt% with respect to the low-fusing point glass composition.

A protection film was formed at a predetermined position on the silicon wafer with the low-fusing point glass film, and the low-fusing point glass film and the silicon substrate were sandblasted to form cavities. Further, through parts were formed in areas corresponding to electrode pads.

Then, the silicon wafer processed in the above-mentioned manner and a sensor forming silicon wafer manufactured in advance were positioned, and a spring clamp temporarily fastened these silicon wafers at their peripheries. Then, the temporarily-fastened silicon wafers were inserted into a hot-press furnace. The internal atmosphere of the hot-press furnace was replaced by nitrogen in the vicinity of a room temperature, and was then heated up to a temperature of 450° C. and pressurized by pressure of 15×10⁴Pa at the same time, whereby joining the silicon wafers.

Then, a joined body acquired in the above-mentioned manner was diced into separate chips. A junction of each chip had a thickness of 30μm and a width of 50μm. A distance between an acceleration sensing part and the junction was 50μm.

Further, the electrode pads of the semiconductor acceleration sensor chip produced in the above-mentioned manner were connected to external electronic circuits by bonding wires to thereby produce a semiconductor acceleration sensor. When the sensing characteristic was evaluated by using the semiconductor acceleration sensor, the acceleration was detected with high accuracy.

Second Embodiment

A semiconductor sensor chip was manufactured in the same manner as the first embodiment except that a silicon wafer composing a cap was joined to a sensor forming silicon wafer in helium gas atmosphere. A gas leak test was then conducted to study the sealing performance of the manufactured semiconductor acceleration sensor chip. The sensor chip was placed in a sealed container, and was pulled in vacuum to analyze the gas in order to check whether the gas leaks from the sensor chip or not. In the test, no helium gas was detected as leaking, and this proved that the cap was completely sealed. Of course, no moisture was found inside the cap. Thus, the use of a low-fusing point glass composition for joining the silicon cap and the silicon substrate as stated above completely seals the inside of the cap regardless of the unevenness of several μm formed by the leading wires.

Third Embodiment

The third embodiment relates to the manufacture of a semiconductor acceleration sensor chip, in which high polymer resin is used to join a silicon cap and a substrate.

First, a polyimide film with a thickness of 50μm, which is the material of a junction layer, was stamped by patterning. Next, the stamped polyimide film was applied to one side of a silicon wafer with a diameter of 6 inches by heat treatment at a temperature of 160° with a load of 30×10⁴Pa being applied.

Then, a protection film was formed at a predetermined position on the silicon wafer with the polyimide film, and the silicon wafer was sandblasted to form cavities. Further, through parts were formed in areas corresponding to electrode pads.

Next, the silicon wafer processed in the above-mentioned manner and a sensor forming silicon wafer manufactured in advance were positioned, and a spring clamp temporarily fastened these silicon wafers at their peripheries. Then, the temporarily-fastened silicon wafers were inserted into a hot-press furnace. The internal atmosphere of the hot-press furnace was replaced by nitrogen at a temperature in close proximity to a room temperature, and was then heated up to a temperature of 450° C. and pressurized by a load of 15×10⁴Pa, so that the silicon wafers were joined together.

Then, a joined body acquired in the above-mentioned manner was diced into separate chips. A junction of each chip had a thickness of 50μm and a width of 50μm. A distance between an acceleration sensing part and the junction was 50μm.

Further, the electrode pads of the semiconductor acceleration sensor chip produced in the above-mentioned manner were connected to external electronic circuits by bonding wires to thereby acquire a semiconductor acceleration sensor. When a semiconductor sensing characteristic was evaluated by using the semiconductor acceleration sensor, the acceleration was detected with high accuracy.

Fourth Embodiment

A semiconductor sensor chip was manufactured in the same manner as the third embodiment except that a silicon wafer composing a cap was joined to a sensor forming silicon wafer in helium gas atmosphere. A gas leak test was then conducted to study the sealing performance of the manufactured semiconductor acceleration sensor chip. The sensor chip was placed in a sealed container, and was pulled in vacuum to analyze the gas in order to check whether the gas leaks from the sensor chip or not. In the test, the helium gas was detected as leaking, but no moisture was detected inside the cap. This proved that the cap was completely sealed. Therefore, if polyimide is used for joining the silicon cap and the substrate, it is possible to prevent the moisture from getting into the cap regardless of the unevenness of several μm formed by the leading wires.

In the above description, the semiconductor acceleration sensor is given as an example of the semiconductor sensor according to the present invention. The present invention, however, should not be restricted to this. For example, the present invention may also be applied to other physical quantity sensors such as a semiconductor pressure sensor and a semiconductor angular acceleration sensor.

As described above, the semiconductor acceleration sensor chip of the above embodiments, in which the silicon cap is provided in such a manner as to cover the acceleration sensing part through the junction layer, does not badly influence the sensing characteristic and provides the excellent sealing performance even if the metal leading wires are formed on the surface of the silicon substrate. The use of the semiconductor acceleration sensor chip according to the above embodiments realizes the manufacture of the semiconductor acceleration sensor with high accuracy and reliability. Moreover, the manufacturing methods of the above embodiments make it possible to mass-produce the semiconductor acceleration sensor chips at a low cost and with high accuracy.

As set forth hereinabove, the semiconductor sensor chip according to the present invention is constructed in such a manner that the silicon wafer (silicon cap) is provided in such a manner as to cover the physical quantity sensing part provided on the silicon wafer (silicon substrate) through the junction layer. Therefore, the semiconductor sensor chip does not badly influence the sensing characteristic, and achieves the excellent sealing performance even if the wiring part comprised of the metal leading wires is formed on the surface of the silicon substrate. The use of the semiconductor sensor chip according to the present invention makes it possible to realize the accurate semiconductor sensor with high accuracy and reliability. Moreover, the use of the manufacturing method according to the present invention makes it possible to mass-produce the semiconductor sensor chips at a low cost and with high accuracy.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A semiconductor sensor chip which comprises a physical quantity sensing part provided on a silicon substrate, and a wiring part for transmitting a physical quantity, sensed by said physical quantity sensing part, as an electric signal, said semiconductor sensor chip comprising:
a silicon cap covering said physical quantity sensing part and a part of said wiring part;
a junction layer where an end of said silicon cap and said silicon substrate are tightly joined; and
wherein there is provided a predetermined clearance between said junction layer and said physical quantity sensing part.

2. A semiconductor chip according to claim 1, wherein said junction layer is formed of a composition including low-fusing point glass.

3. A semiconductor chip according to claim 2, wherein a thermal expansion coefficient of said composition including said low-fusing point glass is not greater than 60×10⁻⁷/° C.

4. A semiconductor chip according to claim 2, wherein said composition including said low-fusing point glass includes a filler selected from a group comprising Pb—Ti—O, Al₂O₃ and Si—Al—O.

5. A semiconductor chip according to claim 2, wherein said low-fusing point glass is selected from a group comprising PbO—B₂O₃, PbO—SiO₂ and PbO—B₂B₃—SiO_{2.}

6. A semiconductor chip according to claim 2, wherein said predetermined clearance is not less than 50μm.

7. A semiconductor chip according to claim 2, wherein said junction layer has a width of not greater than 300μm and a thickness of not greater than 50μm.

8. A semiconductor chip according to claim 4, wherein a maximum particle size of said filler is not greater than 50μm.

9. A semiconductor chip according to claim 1, wherein said junction layer includes high polymer resin.

10. A semiconductor chip according to claim 1, wherein said high polymer resin is polyimide.

11. A semiconductor sensor comprising a semiconductor sensor chip according to claim 1.

12. A method of manufacturing a semiconductor sensor chip, which comprises joining a silicon cap composed of a first silicon wafer and a silicon substrate composed of a second silicon wafer having a physical quantity sensing part and a wiring part through a junction layer composed of a low-fusing point glass composition, said method comprising:
a first step of forming a low-fusing point glass film on a whole surface of one side of said first silicon wafer;
a second step of forming a junction layer, cavities and through parts in said first silicon wafer having said low-fusing point glass film formed in said first step;
a third step of joining said first silicon wafer processed in said first and second steps and said second silicon wafer having said physical quantity sensing part and said wiring part to thus form a joined body; and
a fourth step of dividing said joined body formed in said third step into semiconductor sensor chips.

13. A method of manufacturing a semiconductor sensor chip, which comprises joining a silicon cap composed of a first silicon wafer and a silicon substrate composed of a second silicon wafer having a physical quantity sensing part and a wiring part through a junction layer including high polymer resin, said method comprising:
a first step of forming said junction layer by applying a film, including high polymer resin and stamped in a predetermined shape, to one side of said first silicon wafer;
a second step of forming cavities and through parts in said first silicon wafer having said junction layer formed in said first step;
a third step of joining said first silicon wafer processed in said first and second steps and said second silicon wafer having said physical quantity sensing part and said wiring part to thus form a joined body; and
a fourth step of dicing said joined body formed in said third step into semiconductor sensor chips.

14. A semiconductor sensor ship manufacturing method according to claim 13, wherein said high polymer resin is polyimide.
